(19) United States
(12) Patent Application Publication
(10) Pub. No.: US 2019/0170446 A1
(43) Pub. Date: Jun. 6, 2019

(54) MULTI-TUBE PARALLEL HEAT SPREADER

(71) Applicant: FORCECON TECHNOLOGY CO., LTD., Zhubei City (TW)

(72) Inventors: Sin-Wei HE, Hsinchu County (TW); Chao-Hao Yeh, Hsinchu County (TW); Wei-Han Huang, Hsinchu County (TW); Yong-Da Peng, Hsinchu County (TW)

(73) Assignee: FORCECON TECHNOLOGY CO., LTD.

(21) Appl. No.: 15/833,717

(22) Filed: Dec. 6, 2017

(51) Int. Cl. F28D 15/02; F28D 15/04

(52) U.S. Cl. CPC F28D 15/0266; H05K 7/20263; F28D 15/046

(57) ABSTRACT

A multi-tube parallel heat spreader has at least three conduits disposed in parallel; a first connector fitted onto the first end of each conduit, with one side of the first connector configured with a first connecting plughole for the first end of each conduit to be inserted into, and a first connecting passage inside the first connector that is communicated to each first connecting plughole; a second connector fitted onto the second end of each conduit, with one side configured with a second connecting plughole for the second end of each conduit to be inserted into, and a second connecting passage inside the second connector that is communicated to each second connecting plughole; a working fluid contained in the vacuum interior of each conduit and the first and second connector; a heat conduction base abutting and combined with the conduits, including a heat conductive surface and a supporting surface.

### CROSS-REFERENCE TO RELATED U.S. APPLICATIONS

Not applicable.

### STATEMENT REGARDING FEDERALLY SPONSORED RESEARCH OR DEVELOPMENT

Not applicable.

### NAMES OF PARTIES TO A JOINT RESEARCH AGREEMENT

Not applicable.

### REFERENCE TO AN APPENDIX SUBMITTED ON COMPACT DISC

Not applicable.

### BACKGROUND OF THE INVENTION

### 1. Field of the Invention

The present invention relates generally to a heat spreader, and more particularly to an innovative structural design of a heat spreader which uses multiple tubes for heat circulation.

### 2. Description of Related Art Including Information Disclosed Under 37 CFR 1.97 and 37 CFR 1.98

Current heat spreaders used for cooling product structures are not limited to one design. There are types adopting extended conduit body with internal capillary tissues and working fluid, or oscillatory types adopting circular flow path space with combination of high-percentage working fluid, or heat spreaders featuring a plate-shaped appearance with combination of internal circular or radiating flow path space and integration of capillary tissues.

Thus, to overcome the aforementioned problems of the prior art, it would be an advancement in the art to provide an improved structure that can significantly improve the efficacy.

Therefore, the inventor has provided the present invention of practicability after deliberate design and evaluation based on years of experience in the production, development and design of related products.

### BRIEF SUMMARY OF THE INVENTION

The “multi-tube parallel heat spreader” disclosed in the present invention features an innovative and unique structural design constituted by at least three conduits, first connector, second connector, working fluid and heat conduction base etc. Based on the above design and the related technical features, the present invention realizes an improvement over prior-art structures in that, through the multi-direction recycling space formed by the architecture of multiple interconnected conduits, the working fluid of the heat spreader can be started more easily, and the problem of starting failures can be effectively avoided. In addition, the unique architecture of conduits disclosed in the present invention facilitates formation of a bent shape to meet the demands of various installation environments.

### BRIEF DESCRIPTION OF THE SEVERAL VIEWS OF THE DRAWINGS

FIG. 1 is a combined perspective view of a preferred embodiment of the present invention.

FIG. 2 is an exploded perspective view of a preferred embodiment of the present invention.

FIG. 3 is a partial combined sectional view 1 of a preferred embodiment of the present invention.

FIG. 4 is a partial combined sectional view 2 of a preferred embodiment of the present invention.

FIG. 5 is a partial combined sectional view 3 of a preferred embodiment of the present invention.

FIG. 6 is drawing of an embodiment of the present invention with the conduits formed with a bent portion.

FIG. 7 is drawing of an embodiment of the present invention with the interior of the conduits configured with groove-style capillary tissues.

FIG. 8 is drawing of the application state of an embodiment of the present invention.

FIG. 9 is drawing of an embodiment of the present invention with the second connector formed by sealing the two ends of a tube body.

FIG. 10 is drawing of an embodiment of the present invention with the outer side of the first connector configured with a planar heat conduction portion.

### DETAILED DESCRIPTION OF THE INVENTION

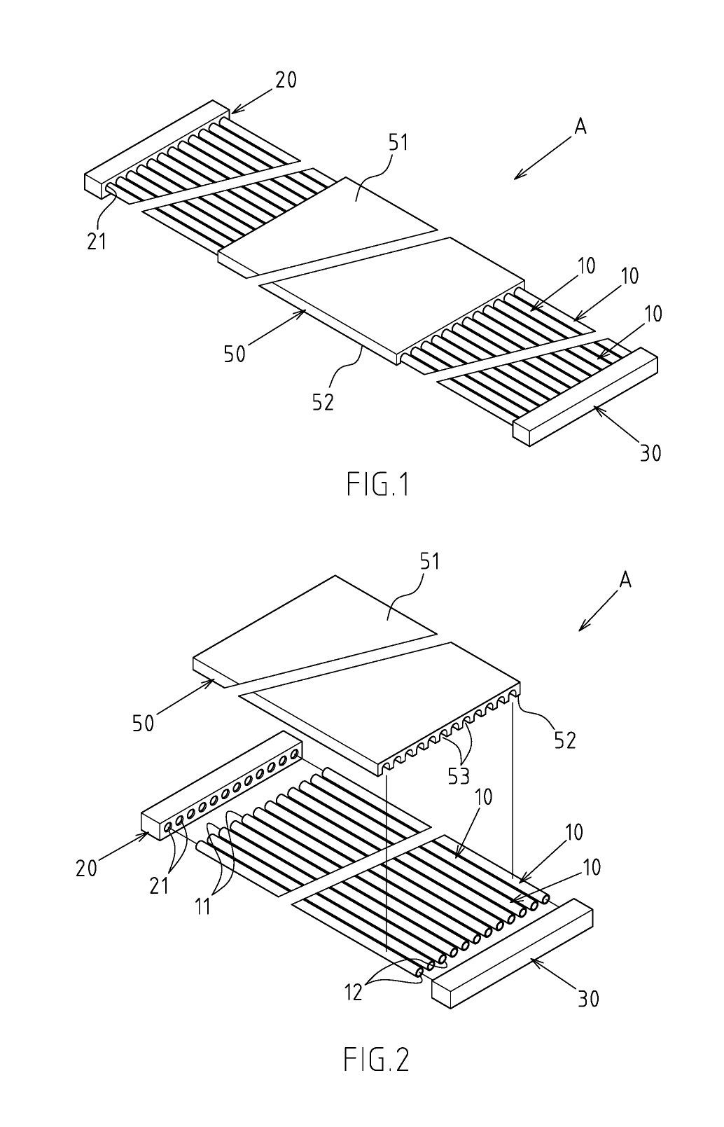

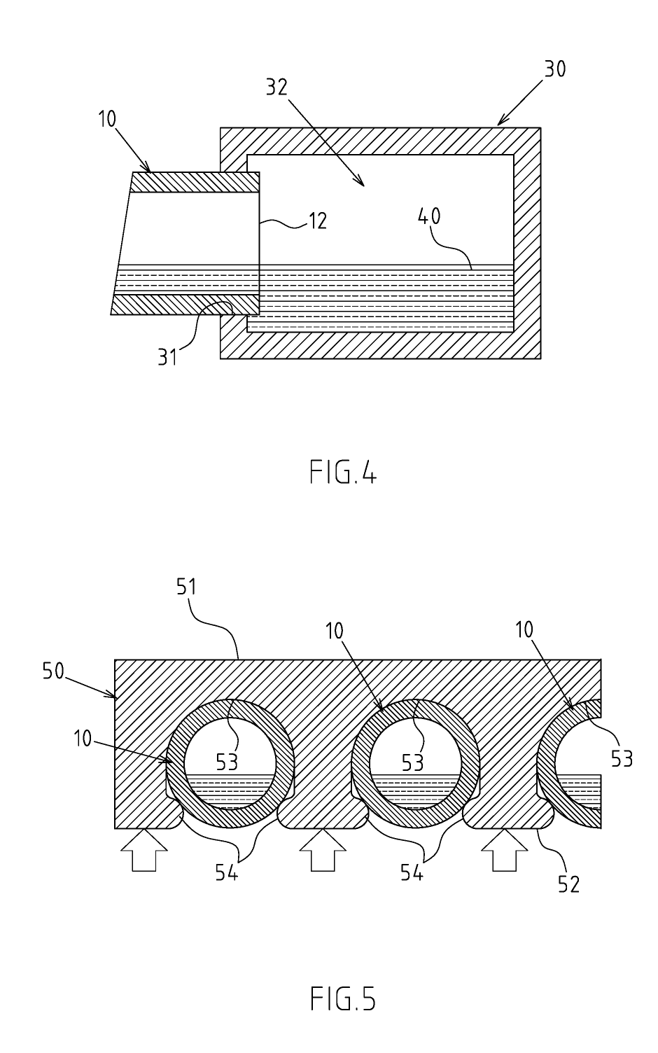

A preferred embodiment of the present invention of a multi-tube parallel heat spreader is disclosed in FIGS. 1, 2, 3, and 4. However, it is to be understood that such an embodiment is illustrative only, and is not intending to limit the scope of patent application.

Said multi-tube parallel heat spreader A comprises: at least three conduits 10, disposed in parallel, each conduit 10 including a first end 11 and a second end 12; a first connector 20, fitted onto the first end 11 of said at least three conduits 10, with one side of said first connector 20 configured with a first connecting plughole 21 for the first end 11 of each of said at least three conduits 10 to be inserted into, and the interior of said first connector 20 having a first connecting passage 22 communicated to each first connecting plughole 21; a second connector 30, fitted onto the second end 12 of said at least three conduits 10, with one side of said second connector 30 configured with a second connecting plughole 31 for the second end 12 of each of said at least three conduits 10 to be inserted into, and the interior of said second connector 30 having a second connecting passage 32 communicated to each second connecting plughole 31; a working fluid 40 (such as pure water, alcohol etc), contained in a free state inside said at least three conduits 10, said first connector 20 and said second connector 30, with the internal space of said at least three conduits 10, said first connector 20 and said second connector 30 being in a vacuum state; at least one heat conduction base 50, abutting and combined with said at least three conduits 10 in at least one position, each heat conduction base 50 including a heat conductive surface 51 and a supporting surface 52 corresponding to the conduits 10.

In particular, the outer diameter of said at least three conduits 10 is from 3 mm to 10 mm, and the length is from 100 mm to 1000 mm. From the tube body dimension scale defined by the present embodiment, it is known that, in practical application, the multi-tube parallel heat spreader A disclosed in the present invention can reach a relatively longer extension for installation. This is impossible for prior-art thermal tube structures (note: the length of extension of existing thermal tubes is normally below 400 mm).

Referring to FIG. 2, in the present embodiment, the supporting surface 52 of the heat conduction base 50 is further configured with at least three caulking grooves 53 for one side of said at least three conduits 10 to be embedded in. And, as shown in FIG. 5, the two opening ends of each caulking grooves 53 are respectively formed into a riveted flange 54 by means of rolling (as indicated by the hollow arrow in the drawing). Said riveted flange 54 is used to limit the corresponding conduit 10.

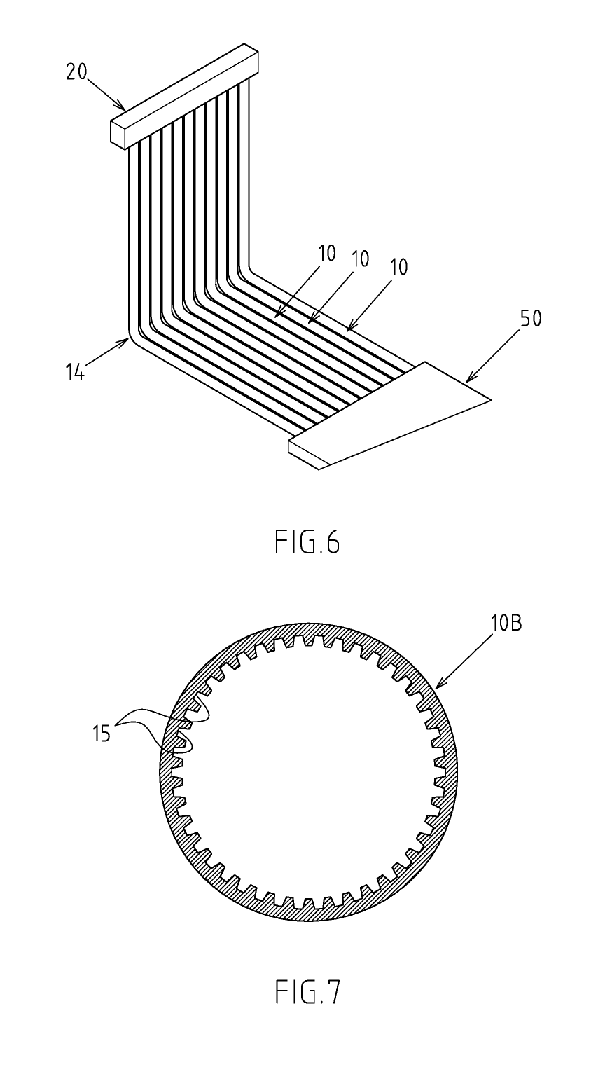

Referring to FIG. 6, in the present embodiment, at relative positions of said at least three conduits 10, one ore more than one bent portions 14 are formed.

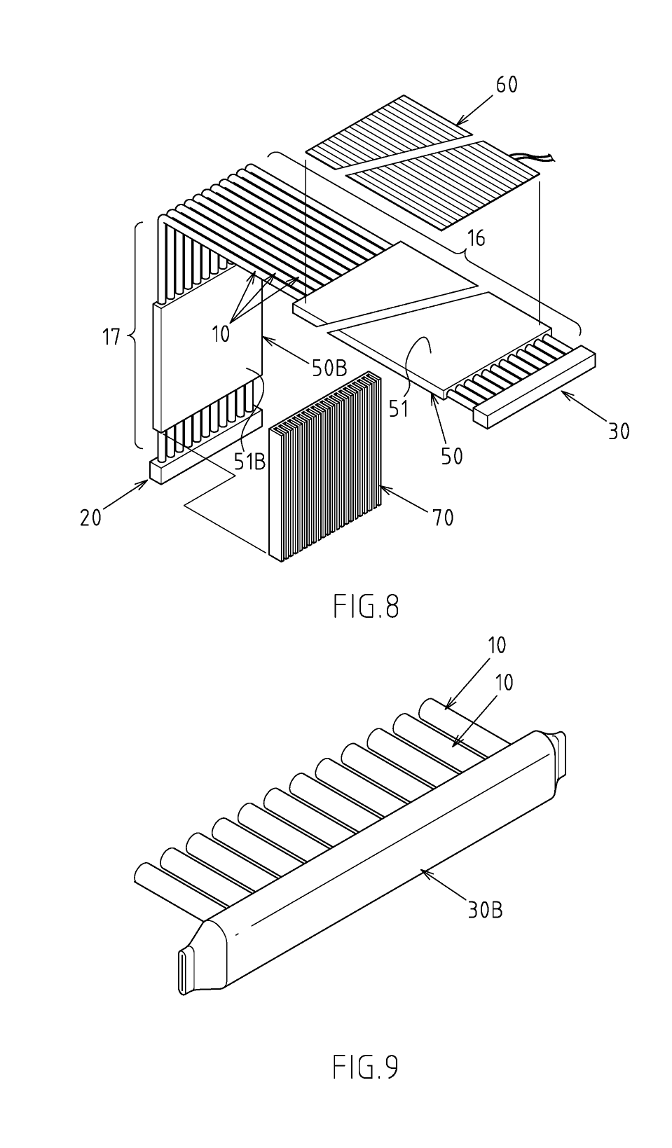

Referring to FIG. 7, the interior of the conduits 10B disclosed in the present embodiment is further configured with groove-style capillary tissue 15.

Referring to FIG. 8, in the present embodiment, said at least three conduits 10 include a heating evaporator section 16 and a cooling condenser section 17, and the heat conduction base 50 abuts and is combined with at least any one of the heating evaporator section 16 or the cooling condenser section 17; in the present embodiment, both the heating evaporator section 16 and the cooling condenser section 17 are configured with a heat conduction base 50, wherein, the heat conductive surface 51 of the heat conduction base 50 configured on the heating evaporator section 16 is for a heat source 60 (being an LED light board in the present embodiment) to abut and bind, while the heat conductive surface 51B of the heat conduction base 50B configured on the cooling condenser section 17 is for a cooling component 70 (being a fin base in the present embodiment) to abut and bind; It is not difficult to see that the heat conduction function of the heat conduction base 50, 50B can be either heating or cooling.

In particular, the percentage of working fluid 40 relative to the internal space of said at least three conduits 10, the first connector 20 and the second connector 30 is from 10% to 80%.

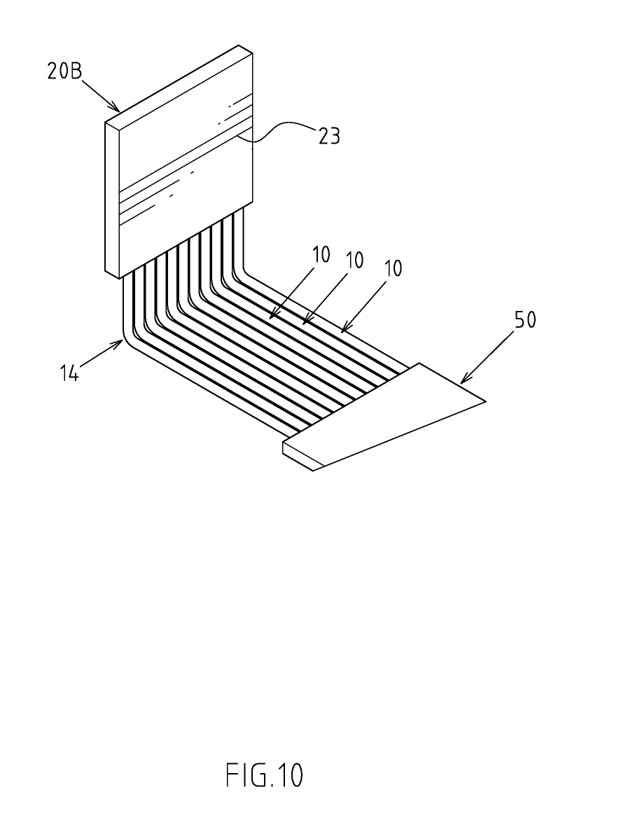

Referring to FIGS. 1 to 4, in the present embodiment, the first connector 20 and second connector 30 are shaped as a rectangular hollow enclosure; in addition, as shown in FIG. 9, the second connector 30B (first connector is also applicable) disclosed in the present embodiment is formed by sealing (such as press fitting) the two ends of a tube body; the tube body disclosed in the present embodiment can be a flat tube as disclosed in the drawing, or a round tube or any other type with no limitation.

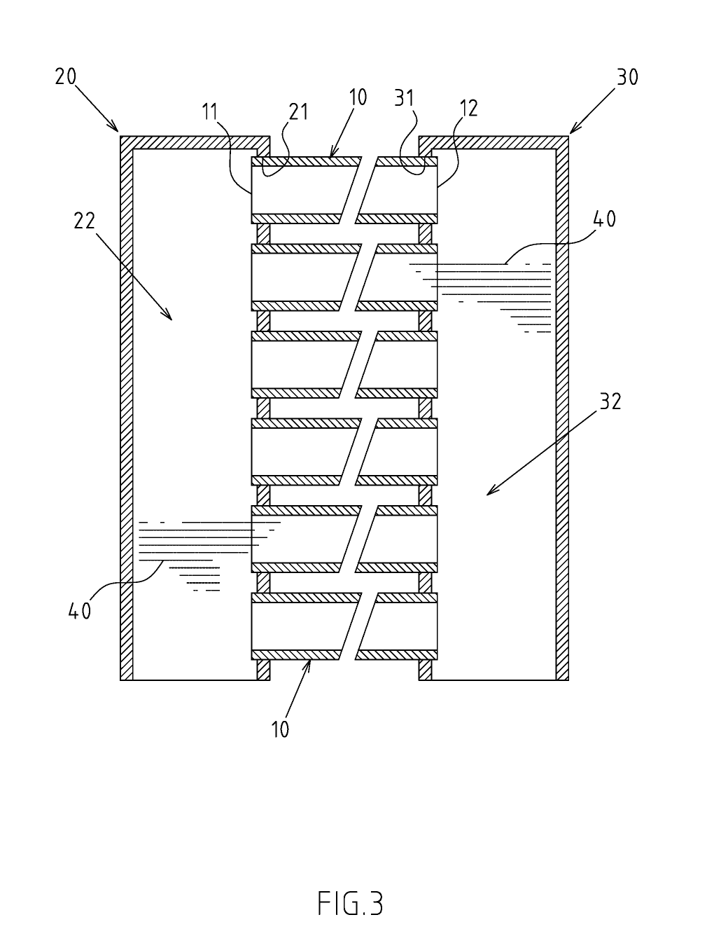

Based on the above-mentioned structural constitution and technical characteristics, the structural design of the multi-tube parallel heat spreader A disclosed in the present invention (as depicted in FIG. 3) combines said at least three parallel-disposed conduits 10 with the first connector 20 and second connector 30 to create a Roman number 1W-shaped conduit architecture, forming a multi-direction circulation space inside, i.e., any two conduits 10 can form one circulation passage through the first connector 20 and second connector 30. Thus, the working fluid 40 inside the heat spreader after evaporation has multiple circulation channels to trigger circulative conduction, making starting more easily and effectively avoiding the problem of starting failure in the prior-art single circulation channel; on the other hand, the conduit architecture of the multi-tube parallel heat spreader A disclosed in the present invention facilitates formation of a bent shape (as shown in FIGS. 6 and 8) to meet the demands of various installation environments.

Moreover, as shown in FIG. 10, the outer side of the first connector 20B (second connector is also applicable) disclosed in the present embodiment is further configured with a planar heat conduction portion 23; the heat conduction function of said planar heat conduction portion 23 in the embodiment can be either heating or cooling. Hence, in practical applications, it can be used to abut and bind with a heat source or a cooling component, so as to meet various application needs of the users. The relationship between the additional planar heat conduction portion 23 disclosed in the present embodiment and the afore-mentioned heat conduction base 50 can be a gain-assisted relationship, or a matching relationship, depending on the actual demand of the user.

I claim:

1. A multi-tube parallel heat spreader comprising:
at least three conduits, disposed in parallel, each conduits including a first end and a second end;
a first connector, fitted onto the first end of said at least three conduits, with one side of the first connector configured with a first connecting plughole for the first end of each of said at last three conduits to be inserted into, and a first connecting passage inside the first connector that is communicated to each first connecting plughole;
a second connector, fitted onto the second end of each of said at least three conduits, with one side of the second connector configured with a second connecting plughole for the second end of each of said at least three conduits to be inserted into, and a second connecting passage inside the second connector that is communicated to each second connecting plughole;
a working fluid, contained in a free state inside said at least three conduits, said first connector and said second connector, the interiors of said at least three conduits, said first connector and said second connector are in a vacuum state; and
at least one heat conduction base, butting and combined with said at least three conduits in at least one position, each of said heat conduction bases including a heat conductive surface and a supporting surface corresponding to said conduits.

2. The device defined in claim 1, wherein the outer diameter of said at least three conduits is from 3 mm to 10 mm, and length is from 100 mm to 1000 mm.

3. The device defined in claim 2, wherein the outer side of at least any one of the first connector or second connector is further configured with a planar heat conduction portion.

4. The device defined in claim 3, wherein the supporting surface of said heat conduction base is further configured with at least three caulking grooves for said at least three conduits to be embedded into, and the two opening sides of each caulking groove is respectively formed into a riveted flange by means of rolling, said riveted flange to be used as a limit against the corresponding conduit.

5. The device defined in claim 4, wherein said at least three conduits comprises a heating evaporator section and a cooling condenser section, and the heat conduction base abuts and is combined with at least any one of the heating evaporator section or the cooling condenser section.

6. The device defined in claim 5, wherein the tube sections of said at least three conduits corresponding to the exterior of the heat conduction base are further formed with one or more than one bent portions.

7. The device defined in claim 6, wherein the interior of each of the conduits is further configured with groove-style capillary tissues.

8. The device defined in claim 7, wherein the percentage of said working fluid relative to the internal space of said at least three conduits, the first connector and the second connector is from 10% to 80%.

9. The device defined in claim 8, wherein said first connector and second connector are shaped as a rectangular hollow enclosure.

10. The device defined in claim 8, wherein said first connector and second connector are formed by sealing the two ends of a tube body.
